(19) United States
(12) Patent Application Publication
(10) Pub. No.: US 2026/0150475 A1
(43) Pub. Date: May 28, 2026

(54) DISPLAY DEVICE

(71) Applicant: AUO Corporation, Hsinchu City (TW)

(72) Inventors: Lung-Jing CHEN, Hsinchu City (TW); Tzu-Chin Huang, Hsunchu City (TW); Chan-Jui Liu, Hsinchu City (TW)

(21) Appl. No.: 19/240,742

(22) Filed: Jun. 17, 2025

(30) Foreign Application Priority Data
Nov. 25, 2024 (TW) 113145395

(51) Int. Cl. H10H 29/856; H10H 29/85

(52) U.S. Cl. CPC H10H 29/856; H10H 29/8517

(57) ABSTRACT

A display device includes a light emitting substrate and a counter substrate opposite to the light emitting substrate. The light emitting substrate includes a first substrate, a reflective pattern layer, light emitting diodes and scattering elements. The reflective pattern layer is on the first substrate and has openings. The light emitting diodes are in the openings. The scattering elements are filled in the openings, and cover the light emitting diodes. The counter substrate includes a second substrate, filter units, a planarization layer and lenses. The filter units are on the second substrate and correspond to the light emitting diodes. The planarization layer is between the second substrate and the filter units, and has recesses corresponding to the light emitting diodes. The lenses are in the recesses and correspond to the light emitting diodes. The refractive index of the lenses is greater than that of the planarization layer.

### CROSS-REFERENCE TO RELATED APPLICATION

This application claims priority to Taiwan Application Serial Number 113145395, filed Nov. 25, 2024, which is herein incorporated by reference in its entirety.

### BACKGROUND

### Field of Invention

The present disclosure relates to a display device. More particularly, the present disclosure relates to a display device including micro light emitting diodes and micro lenses.

### Description of Related Art

Micro light emitting diode (micro LED) display devices have the advantages of power saving, high efficiency, high brightness, and fast response time, etc. However, since the light emission patterns of micro-LEDs are different, and total reflection is easily caused in the stacked structure of the display device due to differences in light output angles and refractive indices, resulting in poor light output efficiency.

### SUMMARY

At least one embodiment of the present disclosure provides a display device which can improve light output efficiency.

The display device according to at least one embodiment of the present disclosure includes a light emitting substrate, a counter substrate disposed opposite to the light emitting substrate, and a filling layer disposed between the light emitting substrate and the counter substrate. The light emitting substrate includes a first substrate, a reflective pattern layer, multiple micro light emitting diodes, and multiple scattering elements. The reflective pattern layer is disposed on the first substrate and has multiple openings. The micro light emitting diodes are disposed in the openings respectively. The scattering elements are filled in the openings respectively and cover the micro light emitting diodes respectively. The counter substrate includes a second substrate, multiple filter units, a planarization layer, and multiple micro lenses. The filter units are disposed on the second substrate and correspond to the micro light emitting diodes respectively. The planarization layer is disposed between the second substrate and the filter units, and has multiple recesses corresponding to the micro light emitting diodes respectively. The micro lenses are disposed in the recesses respectively, correspond to the micro light emitting diodes respectively, and are located between the filter units and the planarization layer. The refractive index of the micro lenses is greater than the refractive index of the planarization layer.

The display device according to at least another embodiment of the present disclosure includes a light emitting substrate, and a counter substrate disposed opposite to the light emitting substrate. The light emitting substrate includes a first substrate, a reflective pattern layer, multiple micro light emitting diodes, and multiple scattering elements. The reflective pattern layer is disposed on the first substrate and has multiple openings. The micro light emitting diodes are disposed in the openings respectively. The scattering elements are filled in the openings respectively and cover the micro light emitting diodes respectively. The counter substrate includes a second substrate, multiple filter units, a planarization layer, and multiple micro lenses. The filter units are disposed on the second substrate and correspond to the micro light emitting diodes respectively. The planarization layer is disposed between the second substrate and the filter units, and has multiple recesses corresponding to the micro light emitting diodes respectively. The micro lenses are disposed in the recesses respectively, correspond to the micro light emitting diodes respectively, and are located between the filter units and the planarization layer. The refractive index of the micro lenses is greater than the refractive index of the planarization layer. The orthographic projections of the micro light emitting diodes on the first substrate are respectively located within the orthographic projection of the micro lenses corresponding to the micro light emitting diodes on the first substrate.

### BRIEF DESCRIPTION OF THE DRAWINGS

FIG. 1 is a partial schematic cross-sectional view of a display device according to at least one embodiment of the present disclosure.

FIG. 2 is an enlarged diagram of region A in FIG. 1.

FIG. 3 a schematic top view of a first substrate, multiple micro light emitting diodes, a planarization layer, and multiple micro lenses according to at least one embodiment of the present disclosure.

FIG. 4 is a partial schematic cross-sectional view of a display device according to at least another embodiment of the present disclosure.

FIG. 5 is total brightness gain curves of display devices with micro lenses of different widths and heights according to at least one embodiment of the present disclosure.

FIG. 6 is normal brightness gain curves of display devices with micro lenses of different widths and heights according to at least one embodiment of the present disclosure.

### DETAILED DESCRIPTION

In the following description, in order to clearly present the technical features of the present disclosure, the dimensions (such as length, width, thickness, and depth) of elements (such as layers, films, substrates, and areas) in the drawings will be enlarged in unequal proportions. Therefore, the description and explanation of the following embodiments are not limited to the sizes and shapes presented by the elements in the drawings, but should cover the sizes, shapes, and deviations of the two due to actual manufacturing processes and/or tolerances. For example, the flat surface shown in the drawings may have rough and/or non-linear characteristics, and the acute angle shown in the drawings may be round. Therefore, the elements presented in the drawings in this case are mainly for illustration, and are not intended to accurately depict the actual shape of the elements, nor are they intended to limit the scope of patent applications in this case.

Furthermore, the words “about”, “approximately” or “substantially” used in the present disclosure not only cover the clearly stated numerical values and numerical ranges, but also cover those that can be understood by a person with ordinary knowledge in the technical field to which the present disclosure belongs. The permissible deviation range can be determined by the error generated during measurement, and the error is caused, for example, by limitations of the measurement system or process conditions. For example, two objects (such as the plane or traces of a substrate) are “substantially parallel” or “substantially perpendicular,” where “substantially parallel” and “substantially perpendicular,” respectively, mean that parallelism and perpendicularity between the two objects can include non-parallelism and non-perpendicularity caused by permissible deviation ranges.

In addition, “about” may mean within one or more standard deviations of the above values, such as within ±30%, ±20%, ±10%, or ±5%. Such words as “about”, “approximately”, or “substantially” as appearing in the present disclosure may be used to select an acceptable range of deviation or standard deviation according to optical properties, etching properties, mechanical properties, or other properties, rather than applying all of the above optical properties, etching properties, mechanical properties, and other properties with a single standard deviation.

The spatial relative terms used in the present disclosure, such as “below,” “under,” “above,” “on,” and the like, are intended to facilitate the recitation of a relative relationship between one element or feature and another as depicted in the drawings. The true meaning of these spatial relative terms includes other orientations. For example, the relationship between one element and another may change from “below” and “under” to “above” and “on” when the drawing is turned 180 degrees up or down. In addition, spatially relative descriptions used in the present disclosure should be interpreted in the same manner.

It should be understood that while the present disclosure may use terms such as “first”, “second”, “third” to describe various elements or features, these elements or features should not be limited by these terms. These terms are primarily used to distinguish one element from another, or one feature from another. In addition, the term “or” as used in the present disclosure may include, as appropriate, any one or a combination of the listed items in association.

Moreover, the present disclosure may be implemented or applied in various other specific embodiments, and the details of the present disclosure may be combined, modified, and altered in various embodiments based on different viewpoints and applications, without departing from the idea of the present disclosure.

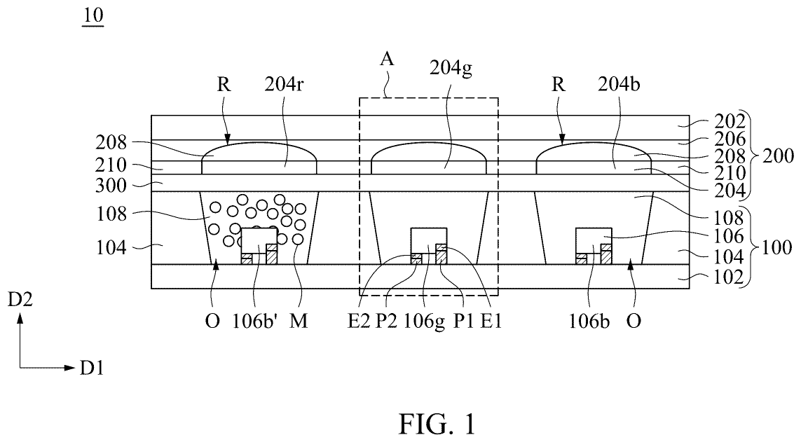

FIG. 1 is a partial schematic cross-sectional view of a display device 10 according to at least one embodiment of the present disclosure. The display device 10 includes a light emitting substrate 100, a counter substrate 200 disposed opposite to the light emitting substrate 100, and a filling layer 300 disposed between the light emitting substrate 100 and the counter substrate 200.

The light emitting substrate 100 includes a first substrate 102, a reflective pattern layer 104, multiple micro light emitting diodes (micro LEDs, μLEDs) 106, and multiple scattering elements 108. The reflective pattern layer 104 is disposed on the first substrate 102 and has multiple openings O. The micro light emitting diodes 106 are disposed in the openings O respectively. The scattering elements 108 are filled in the openings O respectively and cover the micro light emitting diodes 106 respectively.

The counter substrate 200 includes a second substrate 202, multiple filter units 204, a planarization layer 206, and multiple micro lenses 208. The filter units 204 are disposed on the second substrate 202 and correspond to the micro light emitting diodes 106 respectively. The planarization layer 206 is disposed between the second substrate 202 and the filter units 204 and has multiple recesses R. The recesses R correspond to the micro light emitting diodes 106 respectively. The micro lenses 208 are disposed in the recesses R respectively and correspond to the micro light emitting diodes 106 respectively. The micro lenses 208 are located between the filter units 204 and the planarization layer 206, and the refractive index of the micro lenses 208 is greater than the refractive index of the planarization layer 206.

Since the micro lenses 208 are disposed in the recesses R and correspond to the micro light emitting diodes 106, and the refractive index of the micro lenses 208 is greater than the refractive index of the planarization layer 206, the light emitted by the micro light emitting diodes 106 can be refracted through the interface and refractive index difference between the micro lenses 208 and the planarization layer 206, which reduces the total reflection of light at a large angle, thereby effectively improving the light output efficiency. In addition, the light emitted by the micro light emitting diodes 106 is refracted by the interface and refractive index difference between the micro lenses 208 and the planarization layer 206 after passing through the filter units 204, which avoids the situation that the light emitted at a large angle is absorbed by the adjacent filter unit, thereby increasing the range of the viewing angle.

As shown in FIG. 1, the counter substrate 200 further includes multiple light shielding elements 210. The light shielding elements 210 and the filter units 204 are alternately arranged. Since the light emitted by the micro light emitting diodes 106 is refracted by the interface and refractive index difference between the micro lenses 208 and the planarization layer 206 after passing through the filter units 204 and the light shielding elements 210, which avoids the situation that the light emitted at a large angle is absorbed by the light shielding elements 210, thereby increasing the range of the viewing angle.

In addition, the second substrate 202 is free of in direct contact with the micro lenses 208. Through the aforementioned design, the planarization layer 206 is disposed between the second substrate 202 and the micro lenses 208, ensuring that the light emitted by the micro light emitting diodes 106 can be refracted through the interface and refractive index difference between the micro lenses 208 and the planarization layer 206, reducing the situation of total reflection of light at a large angle, thereby effectively improving the light output efficiency.

In some embodiments, the micro light emitting diodes 106 include micro light emitting diodes emitting different colored lights sequentially arranged in a first direction D1 corresponding to the filter units 204 with different colors, for example, including a first micro light emitting diode 106b′, a second micro light emitting diode 106g, and a first micro light emitting diode 106b sequentially arranged in the first direction D1 corresponding to a first filter unit 204r, a second filter unit 204g, and a third filter unit 204b. For example, the first micro light emitting diode 106b, 106b′ and the second micro light emitting diode 106g may be a blue micro light emitting diode and a green micro light emitting diode respectively, and the first filter unit 204r, the second filter unit 204g and the third filter unit 204b may be a red filter unit, a green filter unit and a blue filter unit respectively.

In addition, the scattering elements 108 are sequentially arranged in the first direction D1 corresponding to the filter units 204 with different colors. The scattering element 108 corresponding to the first filter unit 204r may further include a wavelength conversion material M. The wavelength conversion material M may be phosphor or quantum dot (QD), such as silicate, silicon nitride, sulfide, quantum dot, garnet or other suitable materials or a combination thereof, so that the light emitted by the micro light emitting diode 106 can be converted into a desired color light. For example, the wavelength conversion material M can convert the first micro light emitting diode 106b′ that emits blue light into red light.

The micro light emitting diode 106 may be an inorganic light emitting diode with a thickness not greater than 30 micrometers. In addition, as shown in FIG. 1, the micro light emitting diode 106 includes a first electrode E1 and a second electrode E2, and the first electrode E1 and the second electrode E2 are both located on the side of the micro light emitting diode 106 facing the first substrate 102. Therefore, in this embodiment, the micro light emitting diode 106 is a flip-chip horizontal micro light emitting diode (lateral micro LED), and the light emitting substrate 100 further includes a driving circuit (not shown), and a first pad P1 and a second pad P2 electrically connected to the driving circuit and disposed on the first substrate 102. The first electrode E1 and the second electrode E2 of the micro light emitting diode 106 are electrically connected to the first pad P1 and the second pad P2 respectively.

Referring to FIG. 1, in the normal line of the first substrate 102, i.e., in a second direction D2, the filter units 204 overlap the micro light emitting diodes 106 respectively, and the micro lenses 208 overlap the micro light emitting diodes 106 respectively. For example, in the normal line of the first substrate 102, i.e., in the second direction D2, the first filter unit 204r, the second filter unit 204g, and the third filter unit 204b overlap the first micro light emitting diode 106b′, the second micro light emitting diode 106g, and the first micro light emitting diode 106b respectively, and the micro lenses 208 overlap the first micro light emitting diode 106b′, the second micro light emitting diode 106g, and the first micro light emitting diode 106b respectively. In some embodiments, the second direction D2 is substantially perpendicular to the first direction D1.

The first substrate 102 may be a transparent substrate or a non-transparent substrate, and the second substrate 202 may be a transparent substrate. The materials of the first substrate 102 and the second substrate 202 may be quartz, glass, polymer materials or other appropriate materials. The aforementioned polymer materials are, for example, polyethylene terephthalate (PET) or polyimide (PI).

In addition, the reflective pattern layer 104, the scattering elements 108, the filter units 204, the planarization layer 206, the micro lenses 208, the light shielding elements 210 and the filling layer 300 may be formed by a deposition process, an inkjet process, a printing process, a coating process and a photolithography process. For example, the planarization layer 206 may be formed on the second substrate 202, and then a photolithography process and an etching process are used to form the recesses R, and the shape of the recess R includes an arc. Next, the micro lenses 208 are formed in the recesses R. By forming the micro lenses 208 in the recesses R including arcs to ensure that the micro lenses 208 fits into the recesses R of the planarization layer 206, thereby avoiding a gap between the micro lenses 208 and the planarization layer 206 to affect the light output efficiency. In addition, the light emitted by the micro light emitting diodes 106 can be refracted through the arc-shaped interfaces between the micro lenses 208 and the planarization layer 206, reducing the situation of total reflection of light at a large angle, thereby effectively improving the light output efficiency.

The material of the reflective pattern layer 104 may be polymethyl methacrylate, silicon oxide, siloxane, photoresist or other suitable materials or combinations thereof, and may include scattering particles distributed in the aforementioned materials to achieve reflection and scattering. The material of the scattering particles may be, for example, titanium dioxide.

The material of the light shielding elements 210 may be ink or photoresist. The materials of the planarization layer 206, the micro lenses 208 and the filling layer 300 may be organic insulating materials, inorganic insulating materials or a combination thereof. For example, the organic insulating materials may be polyimide, polyamic acid (PAA), polyamide (PA), polyvinyl alcohol (PVA), polyvinyl cinnamate (PVCi), polymethyl methacrylate (PMMA), other suitable photoresist materials or a combination thereof. The inorganic insulating materials may be silicon oxide, silicon nitride, silicon oxynitride, siloxane or other suitable insulating materials.

In some embodiments, the refractive index of the planarization layer 206 may be 1 to 1.5, the refractive index of the micro lenses 208 may be greater than 1.5, the refractive index of the filling layer 300 may be 1.4 to 1.5, the refractive index of the scattering elements 108 may be 1.6 to 1.9, and the refractive index of the filter units 204 may be 1.6 to 1.8. The refractive index of the micro lenses 208 may be greater than the refractive index of the filling layer 300, the refractive index of the scattering elements 108 may be greater than the refractive index of the filling layer 300, and the refractive index of the filter units 204 may be greater than the refractive index of the filling layer 300. The refractive index of the filling layer 300 is less than the refractive indices of the scattering elements 108 and the filter units 204 adjacent to the filling layer 300, which is helpful for light recycling and can improve light output efficiency.

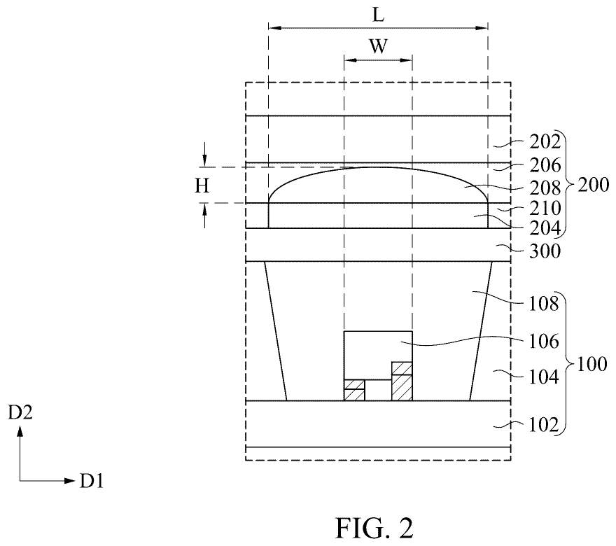

FIG. 2 is an enlarged diagram of region A in FIG. 1. Referring to FIG. 2, in the first direction D1, the micro lens 208 has a first width L, the corresponding micro light emitting diode 106 has a second width W, and the ratio of the first width L of the micro lens 208 to the second width W of the corresponding micro light emitting diode 106 is 3 to 5.5. In the second direction D2, the micro lens 208 has a height H, and a ratio of the height H of the micro lens 208 to the second width W of the corresponding micro light emitting diode 106 is 1.25 to 4.4. In addition, the ratio of the radius of curvature of the micro lens 208 to the second width W of the corresponding micro light emitting diode 106 is 0.8 to 1.6.

By the above-mentioned design, light refraction can be increased to improve light output efficiency. In addition, the first width L of the micro lens 208 is not greater than 40 micrometers to avoid affecting the resolution of the display device, and the height H of the micro lens 208 is not greater than 25 micrometers to achieve the purpose of improving light output efficiency under the current process and material limitations, but the present disclosure is not limited thereto. In other embodiments, the width and height of the micro lens 208 may be adjusted according to different requirements.

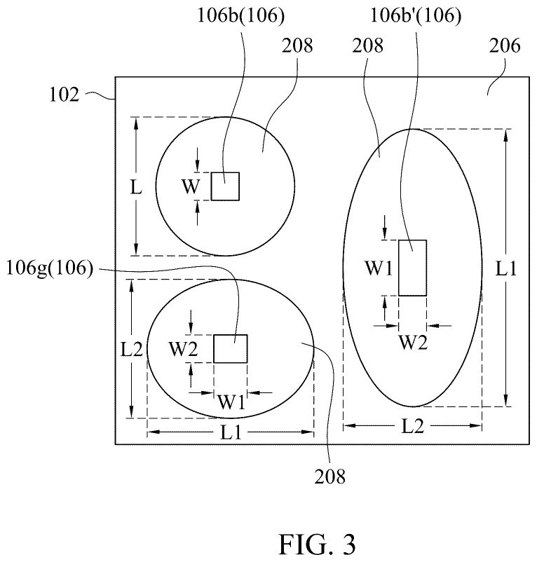

FIG. 3 a schematic top view of a first substrate 102, multiple micro light emitting diodes 106, a planarization layer 206, and multiple micro lenses 208 according to at least one embodiment of the present disclosure. Referring to FIG. 3, the display device includes the micro lenses 208 with different sizes and/or shapes corresponding to the micro light emitting diodes 106b, 106b′, 106g with different sizes and/or shapes.

For example, since the light emitted by the micro light emitting diode 106b′ is converted into light of other color through the wavelength conversion material, such as converting blue light into red light, a larger-sized micro light emitting diode 106b′ is required to compensate for the light loss during the conversion process, and the micro lens 208 corresponding to the micro light emitting diode 106b′ also has a larger size. The micro light emitting diodes 106b and 106g that emit different colored lights, such as blue light and green light, may have different sizes according to the requirements of the display device, and the micro lenses 208 corresponding to the micro light emitting diodes 106b and 106g may also have different sizes. In addition, the orthographic projections of the micro light emitting diodes 106b, 106b′, and 106g on the first substrate 102 are respectively located within the orthographic projections of the micro lenses 208 corresponding to the micro light emitting diodes 106b, 106b′, and 106g on the first substrate 102.

As shown in FIG. 3, the micro light emitting diodes 106b′ and 106g are orthogonally projected on the first substrate 102 to form rectangles with long sides and short sides, the long side have a width W1, and the short side have a width W2. The micro lenses 208 corresponding to the micro light emitting diodes 106b′ and 106g are orthogonally projected on the first substrate 102 to form ellipses with long axis and short axis, the long axis have a width L1, and the short axis have a width L2. The ratio of the width L1 of the long axis of the micro lenses 208 to the width W1 of the long side of the corresponding micro light emitting diodes 106b′ and 106g is 3 to 5.5, and the ratio of the width L2 of the short axis of the micro lenses 208 to the width W2 of the short side of the corresponding micro light emitting diodes 106b′ and 106g is 3 to 5.5. In addition, the micro light emitting diode 106b is orthogonally projected on the first substrate 102 to form a square whose side has a width W, and the micro lens 208 corresponding to the micro light emitting diode 106b is orthogonally projected on the first substrate 102 to form a circle whose diameter has a width L, and the ratio of the width L of the diameter of the micro lens 208 to the width W of the side of the corresponding micro light emitting diode 106 is 3 to 5.5.

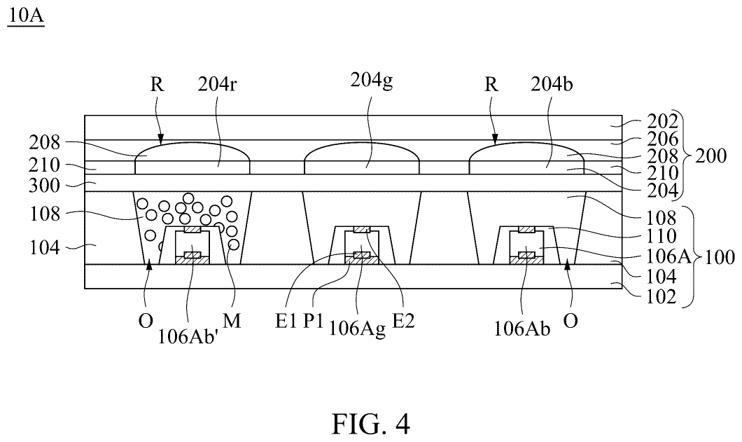

FIG. 4 is a partial schematic cross-sectional view of a display device 10A according to at least another embodiment of the present disclosure. Referring to FIG. 4, the structures, materials, processes and the relative positions of most elements in the embodiment of FIG. 4 and the embodiment of FIG. 1 are the same, so the same features are not repeated here. The differences between the two embodiments are that the first micro light emitting diodes 106Ab, 106Ab′ and the second micro light emitting diode 106Ag of the display device 10A of FIG. 4 are vertical micro light emitting diodes, and the light emitting substrate 100 further includes a protective layer 110 covering the micro light emitting diode 106A, and the scattering element 108 covers the protective layer 110 and the micro light emitting diode 106A.

In detail, as shown in FIG. 4, the micro light emitting diode 106A includes a first electrode E1 and a second electrode E2. The first electrode E1 is located on a side of the micro light emitting diode 106A facing the first substrate 102, and the second electrode E2 is located on a side of the micro light emitting diode 106A facing away from the first substrate 102, i.e., a side facing the counter substrate 200. The light emitting substrate 100 further includes a driving circuit (not shown) and a first pad P1 and a second pad (not shown) electrically connected to the driving circuit. The first electrode E1 and the second electrode E2 of the micro light emitting diode 106A are electrically connected to the first pad P1 and the second pad respectively.

In some embodiments, the refractive index of the protective layer 110 may be 1.5 to 2.3, and the light output efficiency may be improved by selecting a material in the aforementioned refractive index range. The material of the protective layer 110 may be an organic insulating material, an inorganic insulating material, or a combination thereof. For example, the organic insulating material may be polyimide, polyamic acid (PAA), polyamide (PA), polyvinyl alcohol (PVA), polyvinyl cinnamate (PVCi), polymethyl methacrylate (PMMA), other suitable photoresist materials, or a combination thereof. The inorganic insulating material may be silicon oxide, silicon nitride, silicon oxynitride, siloxane, or other suitable insulating materials.

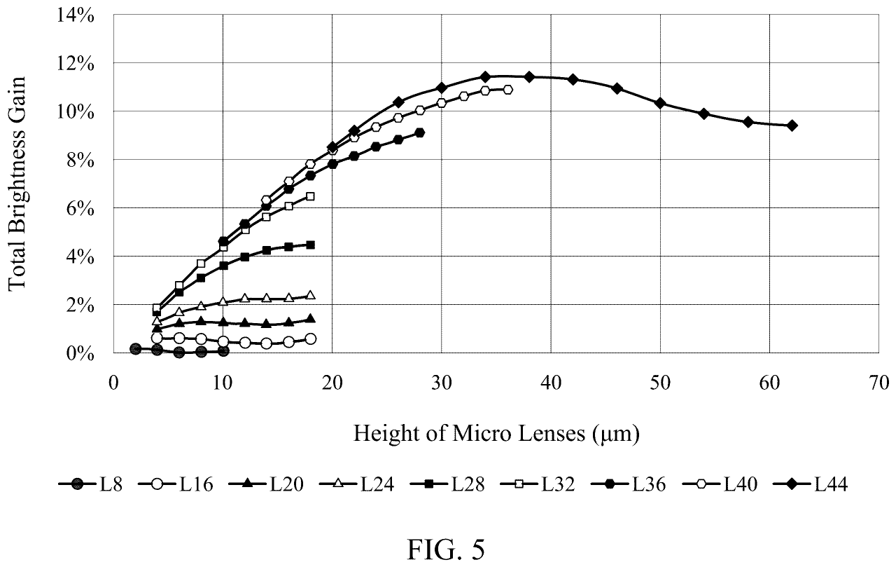

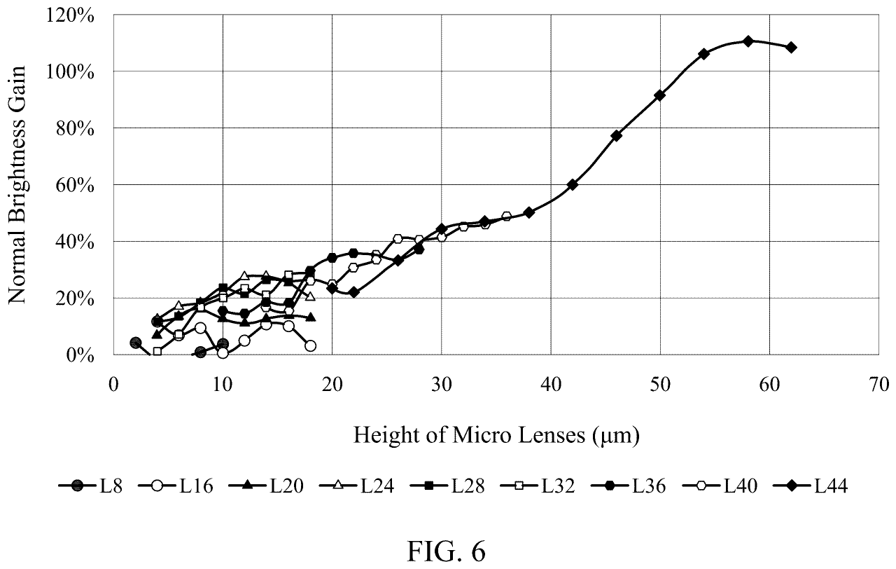

FIG. 5 is total brightness gain curves of display devices with micro lenses of different widths and heights according to at least one embodiment of the present disclosure. FIG. 6 is normal brightness gain curves of display devices with micro lenses of different widths and heights according to at least one embodiment of the present disclosure. Referring to FIG. 5 and FIG. 6, the curves L8, L16, L20, L24, L28, L32, L36, L40, and L44 respectively show the total brightness gain and the normal brightness gain at different heights of micro lenses for embodiments in which micro lenses with widths of 8, 16, 20, 24, 28, 32, 36, 40, and 44 micrometers are combined with micro light emitting diodes with a width of 8 micrometers.

As shown in FIG. 5 and FIG. 6, the embodiment with a micro lens width of 16 micrometers or more has significant gain in both total brightness and normal brightness, and as the height of the micro lens increases, the gain in total brightness and normal brightness also increases. For example, embodiments in which the width and height of the micro lens are more than 24 micrometers and more than 10 micrometers, i.e., the ratio of the width to the width of the micro light emitting diode and the ratio of the height to the width of the micro light emitting diode are more than 3 and more than 1.25 respectively, can achieve a gain of more than 2% in total brightness and a gain of more than 20% in normal brightness.

In summary, in at least one embodiment of the display device of the present disclosure, the micro lenses are disposed in the recesses and correspond to the micro light emitting diodes, and the refractive index of the micro lenses is greater than the refractive index of the planarization layer, the light emitted by the micro light emitting diodes can be refracted through the interface and refractive index difference between the micro lenses and the planarization layer, which reduces the total reflection of light at a large angle, thereby effectively improving the light output efficiency. In addition, the light emitted by the micro light emitting diodes is refracted by the interface and refractive index difference between the micro lenses and the planarization layer after passing through the filter units, which avoids the situation that the light emitted at a large angle is absorbed by the adjacent filter unit, thereby increasing the range of the viewing angle.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims.

What is claimed is:

1. A display device, comprising:
a light emitting substrate, comprising:
a first substrate;
a reflective pattern layer, disposed on the first substrate and having a plurality of openings;
a plurality of micro light emitting diodes, disposed in the openings respectively; and
a plurality of scattering elements, filled in the openings respectively and covering the micro light emitting diodes respectively;
a counter substrate, disposed opposite to the light emitting substrate and comprising:
a second substrate;
a plurality of filter units, disposed on the second substrate and corresponding to the micro light emitting diodes respectively;
a planarization layer, disposed between the second substrate and the filter units, and having a plurality of recesses corresponding to the micro light emitting diodes respectively; and
a plurality of micro lenses, disposed in the recesses respectively, corresponding to the micro light emitting diodes respectively, and located between the filter units and the planarization layer, wherein a refractive index of the micro lenses is greater than a refractive index of the planarization layer; and
a filling layer, disposed between the light emitting substrate and the counter substrate.

2. The display device of claim 1, wherein one of the micro lenses has a first width, one of the micro light emitting diodes corresponding to the one of the micro lenses has a second width, and a ratio of the first width to the second width is 3 to 5.5.

3. The display device of claim 1, wherein one of the micro lenses has a height, one of the micro light emitting diodes corresponding to the one of the micro lenses has a width, and a ratio of the height to the width is 1.25 to 4.4.

4. The display device of claim 1, wherein one of the micro lenses has a radius of curvature, one of the micro light emitting diodes corresponding to the one of the micro lenses has a width, and a ratio of the radius of curvature to the width is 0.8 to 1.6.

5. The display device of claim 1, wherein the second substrate is free of in direct contact with the micro lenses.

6. The display device of claim 1, wherein a refractive index of the micro lenses is greater than a refractive index of the filling layer.

7. The display device of claim 1, wherein a refractive index of the scattering elements is greater than a refractive index of the filling layer.

8. The display device of claim 1, wherein a refractive index of the filter units is greater than a refractive index of the filling layer.

9. The display device of claim 1, wherein a width of one of the micro lenses is not greater than 40 micrometers.

10. The display device of claim 1, wherein a height of one of the micro lenses is not greater than 25 micrometers.

11. The display device of claim 1, wherein a shape of one of the recesses comprises an arc.

12. A display device, comprising:
a light emitting substrate, comprising:
a first substrate;
a reflective pattern layer, disposed on the first substrate and having a plurality of openings;
a plurality of micro light emitting diodes, disposed in the openings respectively; and
a plurality of scattering elements, filled in the openings respectively and covering the micro light emitting diodes respectively; and
a counter substrate, disposed opposite to the light emitting substrate and comprising:
a second substrate;
a plurality of filter units, disposed on the second substrate and corresponding to the micro light emitting diodes respectively;
a planarization layer, disposed between the second substrate and the filter units, and having a plurality of recesses corresponding to the micro light emitting diodes respectively; and
a plurality of micro lenses, disposed in the recesses respectively, corresponding to the micro light emitting diodes respectively, and located between the filter units and the planarization layer, wherein a refractive index of the micro lenses is greater than a refractive index of the planarization layer, and orthographic projections of the micro light emitting diodes on the first substrate are respectively located within orthographic projection of the micro lenses corresponding to the micro light emitting diodes on the first substrate.

13. The display device of claim 12, wherein one of the micro lenses has a first width, one of the micro light emitting diodes corresponding to the one of the micro lenses has a second width, and a ratio of the first width to the second width is 3 to 5.5.

14. The display device of claim 12, wherein one of the micro lenses has a height, one of the micro light emitting diodes corresponding to the one of the micro lenses has a width, and a ratio of the height to the width is 1.25 to 4.4.

15. The display device of claim 12, wherein one of the micro lenses has a radius of curvature, one of the micro light emitting diodes corresponding to the one of the micro lenses has a width, and a ratio of the radius of curvature to the width is 0.8 to 1.6.

16. The display device of claim 12, wherein the second substrate is free of in direct contact with the micro lenses.

17. The display device of claim 12, further comprising:
a filling layer, disposed between the light emitting substrate and the counter substrate.

18. The display device of claim 17, wherein a refractive index of the micro lenses is greater than a refractive index of the filling layer.

19. The display device of claim 17, wherein a refractive index of the scattering elements is greater than a refractive index of the filling layer.

20. The display device of claim 17, wherein a refractive index of the filter units is greater than a refractive index of the filling layer.
